(19) United States
(12) Patent Application Publication
(10) Pub. No.: US 2026/0047229 A1
(43) Pub. Date: Feb. 12, 2026

(54) CDTE PHOTOVOLTAIC MODULE SYSTEMS AND METHODS FOR AUTONOMOUS WATER ELECTROLYSIS

(71) Applicant: SunHydrogen, Inc., Coralville, IA (US)

(72) Inventors: Syed Mubeen Jawahar Hussaini, Coralville, IA (US); Joun Lee, Coralville, IA (US); Wei Cheng, Iowa City, IA (US)

(21) Appl. No.: 19/292,554

(22) Filed: Aug. 6, 2025

Related U.S. Application Data
(60) Provisional application No. 63/680,286, filed on Aug. 7, 2024.

(51) Int. Cl. H10F 77/20; H10F 10/14; H10F 19/90; H10F 71/00

(52) U.S. Cl. CPC H10F 77/219; H10F 10/14; H10F 19/908; H10F 71/138

(57) ABSTRACT

Techniques for water electrolysis employing: a glass substrate layer; a transparent conductive oxide (TCO) layer including TCO electrical disconnects formed in the TCO; a photovoltaic (PV) layer including PV electrical disconnects formed in the PV layer, portions of the PV layer extending into the TCO electrical disconnects; a metal back contact (MBC) layer including MBC electrical disconnects formed in the MBC layer, portions of the MBC layer extending into the PV electrical disconnects; an insulating layer including insulating voids formed in the insulating layer to expose anode and cathode portions of the MBC layer, portions of the insulating layer extending into the MBC electrical disconnects; a metal conductor layer adjacent the insulating layer and including a metal conductor extending into insulating voids to form metal conductors electrically coupled to the exposed anode and cathode portions; catalyst coatings on the metal conductors electrically coupled to the anode and cathode portions.

### RELATED APPLICATIONS

This application claims benefit of and priority to U.S. Provisional Patent application No. 63/680,286 titled “CDTE PHOTOVOLTAIC MODULE SYSTEMS AND METHODS FOR AUTONOMOUS WATER ELECTROLYSIS” and filed Aug. 7, 2024, which is hereby incorporated by reference in its entirety.

### BACKGROUND

Hydrogen is increasingly recognized as a pivotal energy source and carrier for the future. At present, the predominant methods for hydrogen production involve steam reforming of natural gas, crude oil, or biomass. An alternative and more sustainable method is the electrolysis of water, which involves applying an electric current to water or an electrolyte to split it into hydrogen (H₂) on the cathode and oxygen (O₂) on the anode. However, this technique is generally costly due to its energy requirements.

### SUMMARY

In systems where photovoltaics (PV) drive the electrolysis process, the electrolyzer is typically separated from the PV cells. However, this separation can result in efficiency losses. Thus, multiple units are often implemented in the electrolysis process, thereby increasing capital costs. An alternative approach is the integration of the cathode and anode for electrolysis directly on the PV cell, generally in the front and the back, to form a photoelectrochemical (PEC) module, where the PEC reactor is directly placed under water for H₂ production. This PEC approach may require fewer system components, excluding, for example, electrical current collectors, which can substantially lower the capital costs compared to PV and electrolyzer systems. However, challenges for realizing commercial PEC systems exist due, in part, to the ionic losses across a PEC module, which can lower the solar-to-hydrogen conversion efficiency, and the instability of the PV cell due, for example, to photocorrosion within the PEC module submerged in water.

In some instances, a PEC module is generally configured with the cathode and anode integrated on opposite sides of the photovoltaic cell. Such a configuration—with the cathode and anode on opposite sides—may require that the system be small to overcome issues related to ionic conductivity or may necessitate the creation of pathways, such as pores through the photovoltaic material, to facilitate ionic transport. Unfortunately, an approach utilizing the front and back sides of the PV cell for generating O₂ and H₂ may decrease the light absorbance due to light scattering over the generated gas bubbles. Moreover, an approach of exposing both sides of the PV cell under water, or creating numerous pores to improve ionic losses, may significantly increase the corrosion pathways, which can lower the operational life of the PEC module.

In some embodiments, the cathode and anode are positioned in parallel (e.g., side-by-side, in parallel) on the same side of the PV cell. This approach may reduce ionic losses and eliminate the need for complex porous pathways through the PEC module, which can enhance overall system efficiency and reduce production costs. Such an approach may provide significant improvements in PEC based hydrogen production.

In some embodiments, to further optimize the PEC module's efficiency and cost-effectiveness in hydrogen production, advanced PV materials are employed. For example, embodiments may employ Cadmium Telluride (CdTe) solar cells. CdTe PV cells have a substantial presence in the global photovoltaic market and can provide unique properties that facilitate manufacturing and enhance solar energy conversion. In general, CdTe PV cells, constituting approximately 5% of the global PV market, are generally considered the second-most prevalent type of solar cells, trailing behind crystalline silicon (c-Si) cells. This notable market share is attributed to several advantageous characteristics in CdTe technology. For example, CdTe PV cells may exhibit a direct bandgap of 1.45 electron volts (eV), which is well suited for single-junction solar energy conversion and higher than the 1.12 eV indirect bandgap of c-Si cells. Further, CdTe PV cells have shown an ability to absorb ultraviolet (UV) light more effectively than c-Si cells, further improving their energy conversion capabilities.

In some embodiments, CdTe PV cells align well with implementations that integrate parallel positioned cathodes and anodes in PEC modules. As described, the enhanced bandgap and enhanced UV light absorption capabilities of CdTe PV cells may improve photovoltaic efficiency and optimize the performance of PEC modules. Embodiments employing CdTe PV cells in reactors may significantly enhance the practicality and environmental sustainability of hydrogen production, helping to further enhance commercial viability of PEC based hydrogen production.

In some embodiments, the production process of CdTe PV cells is associated with relatively low carbon dioxide emissions, which can help to reduce environmental impact. For example, the production process of CdTe PV cells may involve approximately half the carbon dioxide emissions of c-Si cells. This significant reduction may be attributed to decreased material requirements, as CdTe PV cells are thinner and use less semiconductor material. Moreover, CdTe PV cells may not employ conventional aluminum frames, which can further reduce manufacturing materials and energy requirements, further lessening the environmental footprint. As a result, the integration of CdTe PV cells for the production of green hydrogen may provide a viable approach toward achieving near-zero carbon emissions

In some embodiments, the energy payback period for CdTe PV cells is relatively short. For example, the energy payback period for CdTe PV cells may be under a year, compared to about two years for similarly employed c-Si cells. The energy payback period measures the time required for a PV cell to generate the equivalent amount of energy used in its production, and the above timelines further underscore the potential efficiency and sustainability of CdTe technology.

As will be appreciated in view of the urgent global desire to reduce carbon emissions, particularly in the energy sector, CdTe PV cells may provide a significant growth opportunity in the market. For example, their efficiency, coupled with lower environmental impact, positions them as a viable alternative to traditional c-Si cells, especially in applications where space is limited or weight is a concern. Moreover, ongoing advancements in CdTe cell technology, aimed at further improving their efficiency and lifespan, are likely to further enhance their attractiveness and market potential in the coming years.

A challenge in the integration of CdTe PV cells for the production of green hydrogen may include voltage disparities between hydrogen production from water electrolysis and output achievable from a single-layer CdTe PV cell. While the peak solar-to-electrical energy efficiency of CdTe PV cells may be capable of exceeding 22%, e.g., as demonstrated by the National Renewable Energy Laboratory (NREL), the open-circuit voltage (Voc) of these cells may fall below about 1.1V. Notably, this may be contrasted with a typical requirement of over about 1.6V for efficient water splitting, which may be based on a theoretical minimum energy needed to split water (e.g., about of 1.23 eV), along with additional overpotentials. Overpotentials, in this context, refer to the extra potential required to drive the electrochemical reaction at a desired rate, beyond what is thermodynamically necessary.

In some embodiments, CdTe PV cells are connected in tandem or in-series. Such a configuration may provide relatively high potential that is sufficient to facilitate the water-splitting process for hydrogen production, which may, for example, help overcome photovoltage shortfalls. In some embodiments, multiple PV cells are stacked in tandem. In such an embodiment, a few PV layers with distinct optical bandgaps may be provided to optimize light absorption across the PV layers. In some instances, it can be difficult to stack chalcogenide PV layers (such as CdTe and Cadmium Selenide (CdSe) layers, or the like) to form tandem PV cells with higher voltage. In some embodiments, CdTe PV cells are connected in series with silicon (Si) via external electric connections; however, such an approach may fail to fully capitalize on the unique advantages of using CdTe. In some embodiments, creation of a simple in-series structure, e.g., without external electric connections, may significantly enhance the feasibility and efficiency of using CdTe PV cells for green hydrogen production, while striding towards sustainable energy solutions with a reduced carbon footprint.

As described, provided are embodiments for addressing at least some of the prevailing challenges in harnessing the potential of CdTe PV cells for unassisted water splitting. In certain embodiments, provided are methods for constructing a plurality of CdTe PV layers in series with cathodes and anodes parallelly present on a single CdTe PV cell and using internally integrated electric connections (e.g., without using external electric connections). In some embodiments, this in-series CdTe PV cell, specified as a PV module, includes cathodes and anodes present on one side. This may be suitable for creating a one-sided CdTe PEC module, e.g., after integrating necessary electrocatalysts on the cathodes and anodes. In some embodiments, PEC modules employ parallelly connected, in series, CdTe PV cells integrated with electrocatalysts as Hydrogen modules. Such embodiments may help to overcome limitations of photovoltage shortfall and ionic ohmic losses while efficiently utilizing inherent properties of CdTe. A resulting Hydrogen module, for example, may be capable of generating a requisite voltage for direct, unassisted water electrolysis, which may, in turn, facilitate production of green hydrogen with significantly reduced carbon emissions. Described embodiments may provide an advancement in PEC technology, offering practical, efficient solutions for sustainable hydrogen generation. These solutions may align with the global imperative for clean energy solutions, providing advancement in the field of renewable energy and the application of CdTe PV cells in environmental sustainability.

Provided in some embodiments is a production method for forming CdTe PV cells in series. In certain embodiments, this involves utilizing a CdTe manufacturing processes. Described methods may, for example, simplify the creation of structures suitable for water-splitting applications. For example, described embodiments may facilitate integration of enhanced production techniques into CdTe PV cell production lines, which may offer a cost-effective and efficient pathway to production of CdTe PV cells with enhanced photovoltaic performance.

In some embodiments, scribe patterning and deposition of active layers is employed. This may include, for example, transparent conductive oxides, CdTe, insulators, and electrocatalysts. In some embodiments, a sequence of scribe patterning and deposition of active layers is employed that provides for electrically connecting CdTe layers in series, interspersed with insulators and connectors. Such a process may leverage laser scribing techniques at various stages of the layering process, which may facilitate the precise separation and connection of the CdTe layers. Such an arrangement may be useful in amplifying the photovoltage of the structure connected in series beyond a typical threshold for efficiently driving the water-splitting reaction (e.g., at or above about 1.6V). In certain embodiments, a combination of electron-beam (e-beam) evaporation or sputtering for metal and transparent conductive oxide (TCO) layers, along with techniques such as close-space sublimation (CSS), vapor transport deposition (VTD), sputtering, electrodeposition, chemical vapor deposition (CVD), screen printing, Spray deposition for the CdTe layer, is utilized. This may, for example, ensure relatively high-quality layer formation and optimal PV cell performance.

In some embodiments, described processes incorporate an approach for sealing defects, and coating catalysts on distinct surfaces in between and on the top of CdTe layers. Such processes and resulting arrangements may facilitate generation of oxygen and hydrogen on different surfaces parallelly aligned. This may, for example, enhance the efficiency and stability of the water-splitting process. This can be especially important in embodiments where strategic placement of catalysts plays a critical role in optimizing the solar-to-hydrogen conversion efficiency.

### BRIEF DESCRIPTION OF THE DRAWINGS

FIG. 1 illustrates an example CdTe PV device structure in accordance with one or more embodiments.

FIG. 2 illustrates a cross-section of an example CdTe PV submodule in accordance with one or more embodiments.

FIG. 3 illustrates a top view of an example PV module in accordance with one or more embodiments.

FIGS. 4A and 4B illustrate a top view of example Hydrogen modules in accordance with one or more embodiments.

FIGS. 5A and 5B illustrate example manufacturing processes for Hydrogen modules in accordance with one or more embodiments.

FIG. 6 is a diagram that illustrates an example computer system in accordance with one or more embodiments.

While this disclosure is susceptible to various PV submodule modifications and alternative forms, specific example embodiments are shown and described. The drawings may not be to scale. The drawings and the detailed description are not intended to limit the disclosure to the form disclosed, but are intended to disclose modifications, equivalents, and alternatives falling within the spirit and scope of the present disclosure as defined by the claims.

### DESCRIPTION

Various objects, features, characteristics, and advantages of the invention will become apparent and more readily appreciated from the following description of the embodiments, taken in conjunction with the accompanying drawings and the appended claims, all of which form a part of this specification. In the Drawings, like reference numerals may be utilized to designate corresponding or similar parts in the various Figures, and the various elements depicted are not necessarily drawn to scale.

Certain aspects described pertain to configurations of CdTe PV cells arranged sequentially, in series, to, for example, create a PV submodule with catalysts for oxygen and hydrogen evolution placed on the top of the PV cells. Such a series connection may significantly elevate overall photovoltage of the submodule. This may be attributable to a cumulative effect of the voltage outputs of individual cells when connected end-to-end. For example, each cell may contribute its generated voltage to the total voltage of the submodule, resulting in a compounded increase in the total voltage of the submodule. Such an in-series architecture may provide relatively high voltage levels that provide for effectively driving chemical reactions, such as the water-splitting process for hydrogen production. Such embodiments may eliminate a need for (and thus may not employ) external energy sources.

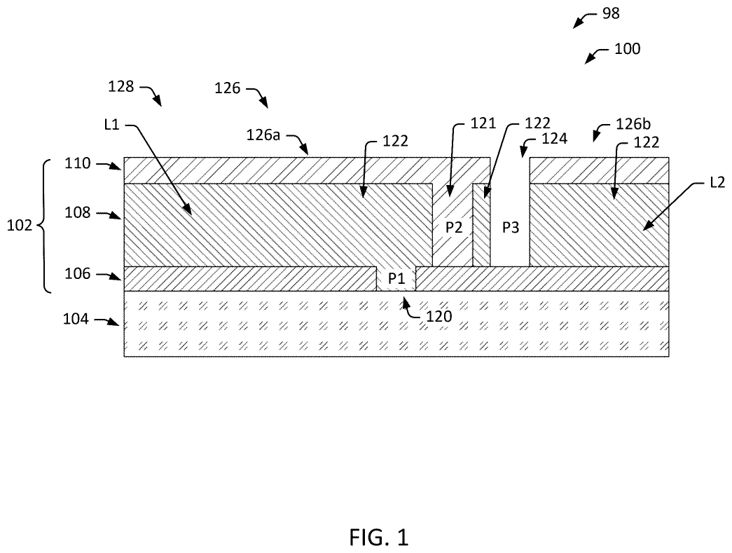

Referring generally to the figures, FIG. 1 illustrates an example CdTe PV device structure in accordance with one or more embodiments. For example, FIG. 1 illustrates a cross section of an example in-series CdTe PV cell structure 98 which forms a PV submodule 100. In such an embodiment, a transparent conductive oxide (TCO) layer on a glass substrate may be first scribed (P1) to disconnect the electrical connection. An absorber, e.g., a PV layer, may be deposited on the top of the TCO layer followed by a second scribing (P2) that disconnects the absorber's electric conductivity without damaging the TCO layer. A third layer may be deposited on the top of the absorber. This third layer may be a conductive metal that serves as a back contact where the metal layer is scribed (P3) to separate the electric connections without damaging the underlying TCO layer. Layer 1 (L1) and layer 2 (L2) may, for example, be connected in series where the output voltages add together while the current (amperage) remains the same. A plurality of such PV submodules may be connected in parallel, forming a PV module, where, for example, the output amperages add together while the output voltage remains the same as achieved in the submodules. The PV layer may be formed of one or more of: cadmium telluride (CdTe), cadmium selenide (CdSe), silicon (Si), gallium arsenide (GaAs), copper indium gallium selenide (CIGS), or perovskite with a corresponding window layer where applicable.

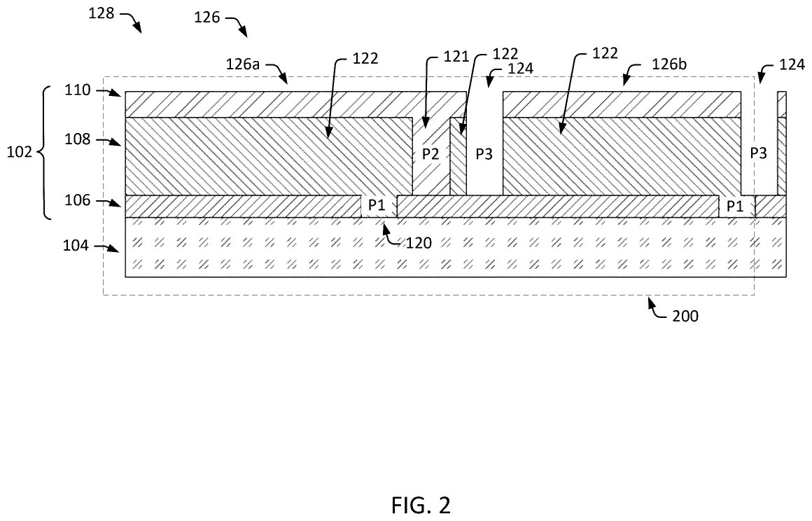

FIG. 2 illustrates a cross-section of an example CdTe PV submodule in accordance with one or more embodiments. For example, FIG. 2 shows a cross-section of an example CdTe PV submodule 200 where the series connection is limited to two CdTe PV layers. In such an embodiment, after the deposition of a metal back contact layer, a third scribing may be applied between two metal back contacts touching the TCO, which may create a disconnect 124 in the TCO layer. In an embodiment where the absorber, which may, for example, include a semiconductor, has much less conductivity compared to the TCO and metal contacts, the charges may pass vertically rather than parallelly. This may, in turn, provide two CdTe layers connected in series. A same or similar approach may be used to create an in-series PV submodule comprising additional (e.g., three) CdTe layers.

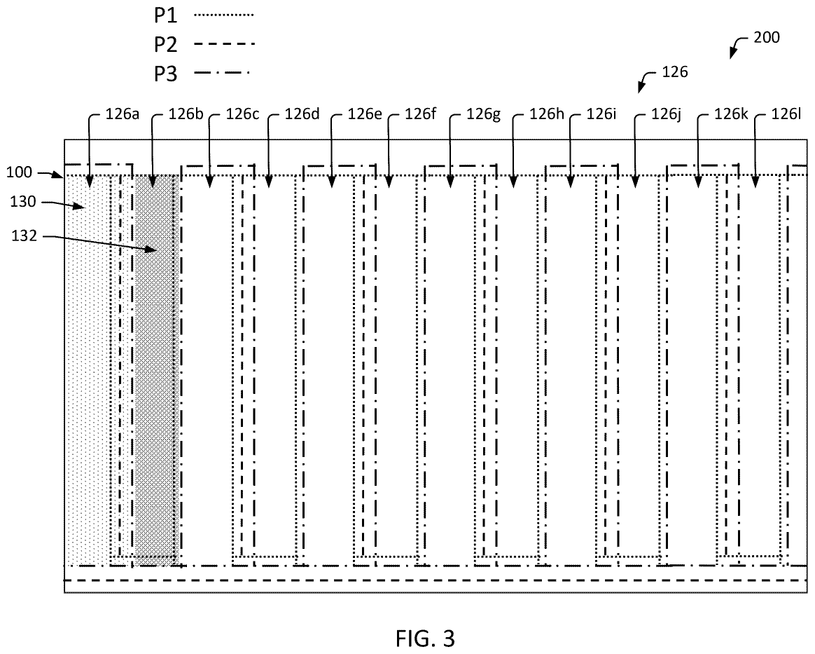

FIG. 3 illustrates a top view of an example PV module in accordance with one or more embodiments. For example, FIG. 3 illustrates the top view of an example PV module that includes six fully formed PV submodules of two CdTe PV layers connected in series. The submodules may be electrically isolated from each other forming five cathode and anode pairs, which may be available as reaction sites for water splitting.

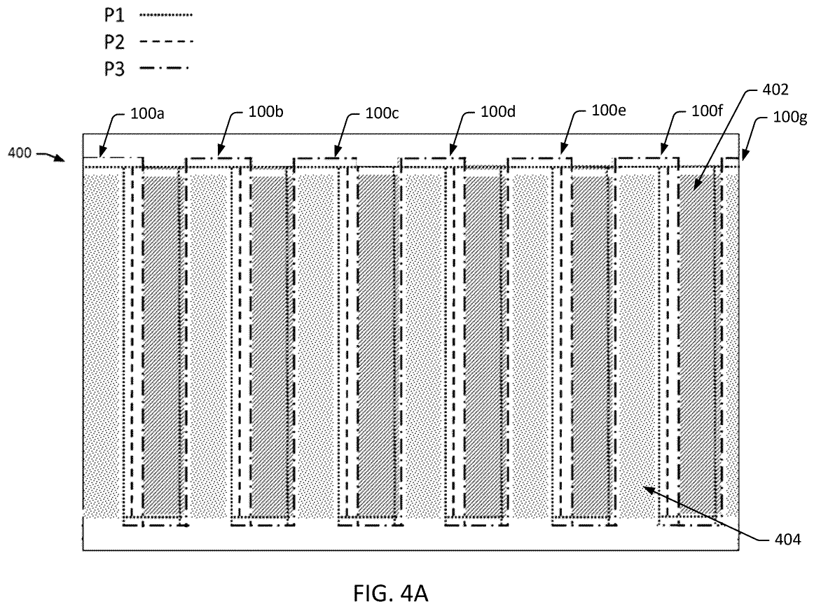

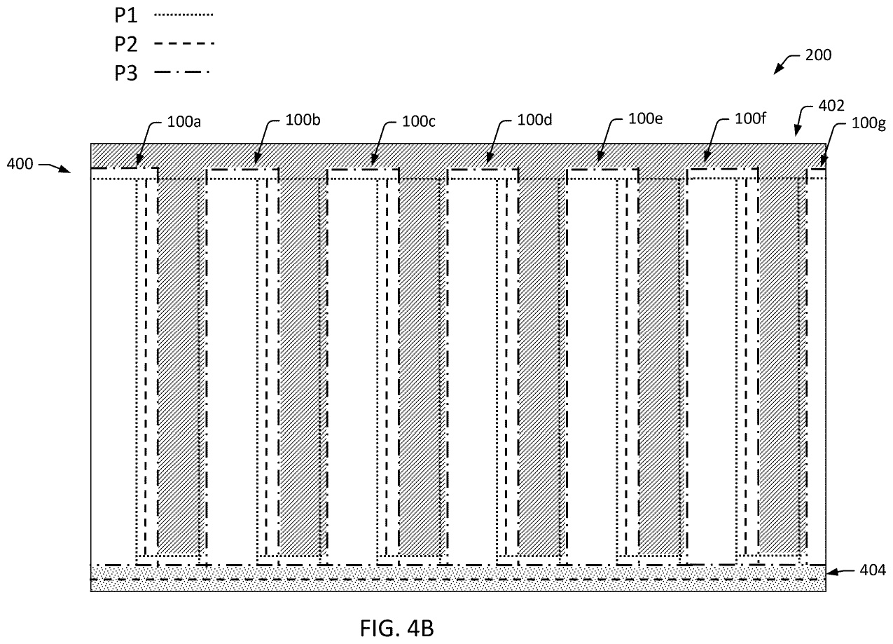

FIG. 4 illustrates a top view of Hydrogen modules in accordance with one or more embodiments. For example, FIG. 4 illustrates side and top views of Hydrogen modules that include six fully formed Hydrogen submodules. In some embodiments, oxygen evolution reaction (OER) catalysts are coated on the top of the anodes and hydrogen evolution reaction (HER) catalysts are coated on the cathodes. The OER and HER catalysts may be deposited on a metal conductor using conductive pastes, conductive tapes, soldering, welding, or another method of attachment. Two Hydrogen submodules may mirror each other in decalcomania, where, for example, the anode of the first Hydrogen submodule is positioned adjacent to the next Hydrogen submodule. The cathode areas coated with HER catalysts (HEC), such as platinum (Pt), may be smaller than the anode areas coated with OER catalyst (OEC) due to the higher catalytic efficiency of HER, which may, in turn, require less catalyst area for HER. In water splitting reactions, the surface area for the HEC may be significantly smaller than that for the OEC, for example, when platinum is utilized. This may be due to the intrinsic catalytic properties of platinum, which may exhibit exceptionally high activity for the hydrogen evolution reaction (HER). Platinum's ability to facilitate the reduction of protons to hydrogen gas efficiently may provide for even a relatively small surface area of Pt being able to achieve high catalytic performance, which can reduce the need for extensive catalyst coverage. Conversely, the oxygen evolution reaction (OER) may be kinetically slower and generally require more active sites to achieve comparable reaction rates. Thus, materials used for OER, such as iridium oxide or nickel-iron layered double hydroxides, may need relatively large surface areas to provide sufficient active sites for effective oxygen evolution. Consequently, in a water-splitting apparatus, the disparity in the required catalyst areas may reflect the differing catalytic efficiencies and reaction kinetics of the materials used for HER and OER.

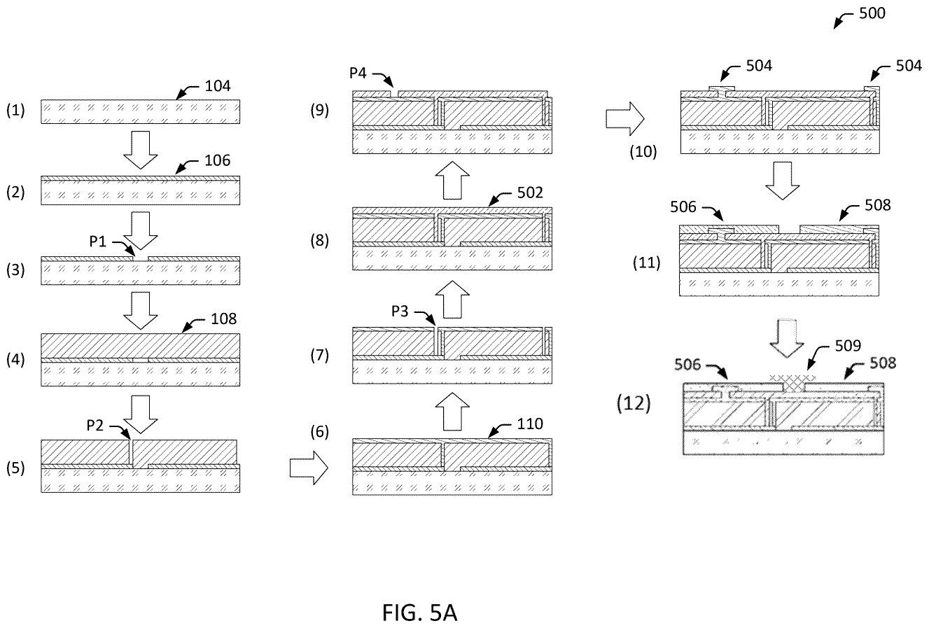

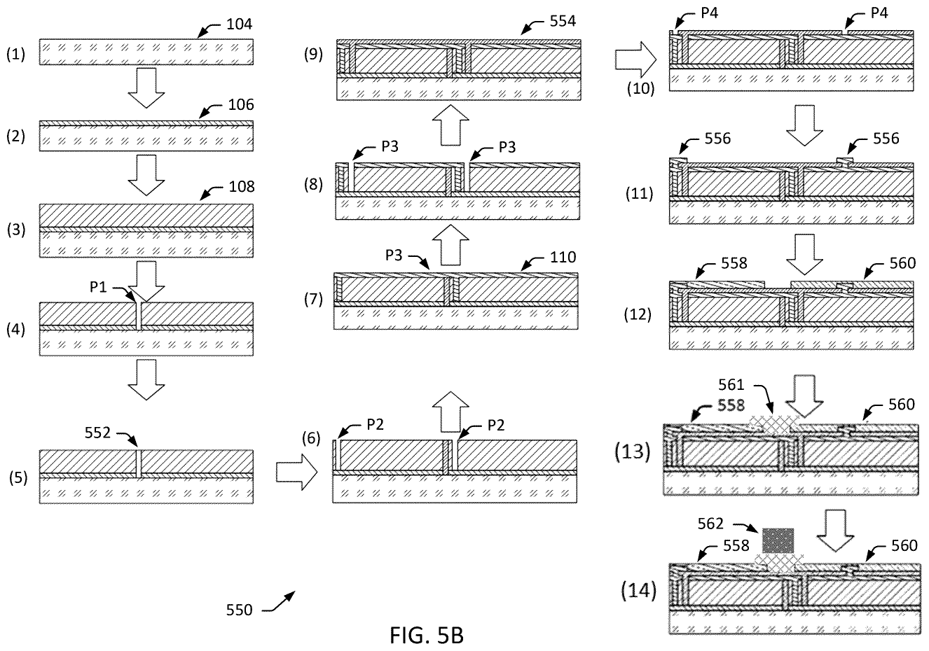

FIGS. 5A and 5B illustrate example manufacturing processes for Hydrogen modules in accordance with one or more embodiments. For example, FIG. 5A illustrates an example manufacturing process for Hydrogen modules showing a zoomed-in cross-sectional view of two CdTe layers connected in series. Such a process may, for example, include the following: (1) forming/providing a glass substrate; (2) depositing a layer (or “coating”) of TCO on the glass substrate; (3) scribing to divide TCO layers for isolation; (4) depositing a semiconductor absorber as a PV layer; (5) scribing to disconnect PV layers to form a number of unit PV layers; (6) depositing of a metal back contact layer; (7) scribing to electrically disconnect the metal contacts and to isolate two PV layers forming one PV module; (8) applying insulating and protecting material; (9) scribing to expose a portion of anode and cathode surfaces; (10) depositing a metal conductor on the exposed cathode and anode surface; (11) depositing a coating of HER and OER catalysts on the metal conductor; and (12) sealing the edges of the catalyst layers with insulting and protecting material.

FIG. 5B illustrates a second example manufacturing process for Hydrogen modules showing a zoomed-in cross-sectional view of two CdTe layers connected in series. Such a process may include, for example, the following: (1) providing a glass substrate; (2) depositing a layer (or “coating”) of TCO on the glass substrate; (3) depositing a semiconductor absorber as a PV layer; (4) scribing to divide TCO and absorber layers for isolation; (5) depositing an insulator inside the scribed patterns; (6) scribing to disconnect PV layers to form a number of unit PV layers; (7) deposition of metal back contact layer; (8) scribing to electrically disconnect the metal contacts and to isolate two PV layers forming one PV module; (9) applying insulating and protecting material layer; (10) scribing the insulating and protecting material layer to expose a portion of anode and cathode surfaces; (11) depositing a metal conductor on the exposed cathode and anode surface; (12) depositing a coating of HER and OER catalysts on the metal conductor; (13) sealing the edges of the catalyst layers with insulting and protecting material; and (14) integrating membrane separators.

Referring in more detail to the figures, FIG. 1 illustrates a side view of a CdTe PV submodule structure (or “PV submodule”) 100 in accordance with one or more embodiments. In the illustrated embodiment, PV submodule 100 includes a CdTe PV submodule structure 102 deposited on a glass substrate 104. Glass substrate 104 may form a base layer of PV submodule 100 and be coated with a transparent conductive oxide (TCO) layer 106. In such an embodiment, TCO layer 106 may facilitate electrical conductivity in the plane of the device while allowing light to pass through to one or more active layers, such as CdTe PV layer 108. A window layer forming p-n junction, along with a graded absorber layer to enhance carrier collection, such as layers comprising CdS, CdSe or CdSeTe, may be included in the CdTe PV layer following the same layer configuration as the CdTe absorber. A CdTe layer 108 may be deposited on TCO layer 106. In such an embodiment, CdTe layer 108 may form an effective absorber layer. As illustrated, a back contact layer 110 may be deposited on CdTe layer 108. In such an embodiment, back contact layer 110 may be, for example, a metal that forms a consistent and conductive back contact layer. In some embodiments, a portion of CdTe layer 108 extends through TCO layer 106 and contacts glass substrate 104 (e.g., as shown at Pl and electrical connection break (or “disconnect”) 120). In some embodiments, a portion of back contact layer 110 extends through CdTe layer 108 and contacts TCO layer 106 (e.g., as shown at P2 and electrical connection break (or “disconnect”) 121).

In some embodiments, construction of PV submodule 100 includes iterative steps of layering and scribing. For example, a layer may be deposited on a substructure, the deposited layer may be scribed, the next layer deposited and scribed, and so forth. In some embodiments, an initial step in constructing PV submodule 100 involves depositing TCO layer 106 on glass substrate 104.

In some embodiments, following the deposition of TCO layer 106 on glass substrate 104, a first scribing operation is conducted on TCO layer 106 (e.g., as illustrated by scribing point P1) to form one or more electrical connection breaks 120 in TCO layer 106. In such an embodiment, such electrical connection breaks 120 may create electrically isolated patterned platforms, allowing multiple PV submodules to be created (or deposited) on a sheet of glass substrate 104. This may, for example, prepare a resulting substrate (e.g., including glass substrate 104 and scribed TCO layer 106) for the subsequent deposition of a next layer, such as semiconductor CdTe layer 108.

In some embodiments, following the deposition of TCO layer 106 and the forming of any suitable electrical connection breaks 120 (e.g., by way of a first scribing operation), CdTe PV layer 108, which may include a window and graded absorber layer, is deposited on TCO layer 106 (and into the formed electrical connection breaks 120 where present) using a suitable deposition technique, such as one or more of close-spaced sublimation (CSS), vapor transport deposition, electrodeposition, physical vapor deposition, or sputtering, which may, for example, contribute to CdTe layer 108 forming an absorber layer. CdTe layer 108 may be formed of, or otherwise include, a semiconductor absorber designed for photovoltaic applications. Such a semiconductor absorber may function by absorbing photons from incident light, resulting in the generation of electron-hole pairs. These charge carriers may then be separated and collected by an electric field within the semiconductor absorber material, creating a flow of electricity. The efficiency of this process may be influenced, for example, by the semiconductor's band gap, which may determine the range of photon energies it can absorb. In some embodiments, optimal materials are selected to maximize the absorption of the solar spectrum, thereby enhancing the conversion efficiency of light to electrical energy.

In some embodiments, following deposition of CdTe layer 108 on TCO layer 106, a second scribing operation is conducted on CdTe layer 108 (e.g., as illustrated by scribing point P2) to form one or more individual photovoltaic cells 122 in CdTe layer 108. Separating the CdTe layer within a submodule platform created by electrical connection breaks 120 may enable the formation of two CdTe PV cells in each PV submodule. The scribing process of photovoltaic cells 122 may create two or more isolated CdTe layers (e.g., left and right portions of CdTe layer 108), which, for example, may later be connected in series to increase the output voltage (e.g., to a level above the required voltage for generating hydrogen from water). In some embodiments, unscribed CdTe layer 108 forms a continuous semiconductor layer, and photovoltaic cells 122 are formed therein. This deposition of a continuous layer and scribing may, for example, ensure that each photovoltaic cell 122 functions independently of one another within the resulting panel structure of PV submodule 100.

In some embodiments, following deposition of CdTe layer 108 and formation of separate photovoltaic cells 122 (e.g., by way of a second scribe operation), back contact layer 110 (e.g., composed of metal), is deposited on CdTe layer 108 (and into photovoltaic cells 122 where present). The back contact layer 110 may be deposited using a suitable technique, such as one or more of sputtering, and electron-beam (e-beam) evaporation, which may, for example, facilitate forming a consistent and conductive back contact layer 110.

In some embodiments, following deposition of back contact layer 110, a third scribing operation is conducted on back contact layer 110 and CdTe layer 108 (e.g., as illustrated by scribing point P3) to form one or more electrical connection break (or “disconnect”) 124. In such an embodiment, electrical disconnects 124 may provide for disconnecting back contact layer 110 (and, in some instances, CdTe layer 108) from adjacent PV cells 126 (e.g., creating a disconnect between elements of a first PV cell 126a and a second/adjacent PV cell 126b). Such a disconnect may, for example, electrically and physically isolate individual CdTe layers within the PV module and ensure that each PV cell 126 can operate independently of other PV cells (e.g., PV cell 126a operates independently of PV cell 126b), which may contribute to enhancing overall efficiency and performance of a resulting PV module 128 (e.g., the PV module formed as a result of the described process).

Accordingly, described embodiments may provide fabrication of an efficient CdTe-based high photovoltaic device by way of sequential layering and scribing processes.

FIG. 2 illustrates a side view of a PV module 200 that includes multiple PV cells 126 (e.g., PV cells 126a and 126b) in series, in accordance with one or more embodiments. In the illustrated embodiment, CdTe PV submodule structure 102 provides a pair of PV cells 126, including PV cell 126a and PV cell 126b that are interconnected in series, which may, for example, be formed through the aforementioned process. The back contact 110 may serve as the positive terminal (anode), while the TCO layer 106 may function as the negative terminal (cathode). The two CdTe layers, 126a and 126b, may be connected to opposite terminals, TCO layer 106 and back contact 110, forming a series connection that, for example, increases the voltage while maintaining the same current. Such a series connection may provide a suitable photovoltage for efficient water electrolysis. For example, the illustrated series connection may yield a photovoltage of at least 1.6V, which, in some instances, may be considered a minimum photovoltage to efficiently facilitate water electrolysis. Incorporating additional PV cells 126 in series within CdTe PV submodule 102, may, for example, further elevate the photovoltage, potentially surpassing a photovoltage of 2V, which may, in turn, further enhance the water-splitting efficiency and the overall energy output of a resulting PV module.

FIG. 3 illustrates a top view of a PV module 200 in accordance with one or more embodiments. The diagram illustrates example isolation of individual PV cells 126 forming PV submodule 100 (e.g., including PV cells 126a-126l) which may be achieved, for example, through the scribing operations described. The scribes (e.g., represented by lines P1, P2 and P3) may create disconnects (e.g., separations) between the semiconductor layers (e.g., separations between respective portions of CdTe layer 108) and the back contacts (e.g., separations between respective portions of back contact layer 110). This may effectively delineate the boundaries of each PV cell 126, and it may form series connections within a PV submodule 200 and parallel connections among the PV submodules 200. The series connections may, for example, be made through positive and negative terminals, e.g., as illustrated in FIG. 2. Parallel connections may, for example, be established through the positive terminals on the back contact 110. In such an embodiment, resulting PV cells 126 may be effectively linked in series. Such a configuration may designate discrete regions to function as the cathode 130 and anode 132. Cathode/anode pairs may, for example, be separated by electrical disconnects, such as gaps in conductive materials, created via scribing or absence of material deposited therebetween.

In some embodiments, gaps created during the last scribing process (e.g., disconnects P3) are filled with polymers to prevent or otherwise inhibit corrosion within the layers. For example, hydrogen evolution reaction (HER) catalysts may be subsequently deposited on the cathode areas and oxygen evolution reaction (OER) catalysts may be applied to the anode areas, which may, in turn, provide for efficient hydrogen production.

In some embodiments, a protective layer is applied to the surface of PV cells 126 to seal defects and enhance durability during water electrolysis. This may, for example, be achieved by spin-coating a layer of photoresist onto the outer surface(s) of PV cell(s) 126, such as on the back contact layer 110. In some embodiments, the protective layer includes a tape, film, or the like. For example, a tape or film may be applied onto the outer surface(s) of PV cell(s) 126, such as on the back contact layer 110, using a pressure-sensitive or heat-sensitive adhesive to adhere the tape or film to the surface.

In some embodiments, for positive photoresists, UV light is directed onto the top surface of PV cell(s) 126. In regions with defects, such as holes, the exposure to UV light may be reduced, resulting in a lower degree of photoresist curing in these areas. Consequently, the uncured photoresist may remain in the defects after development, providing a protective barrier against corrosion during the electrolysis process.

In some embodiments, for negative photoresists, the application involves illuminating UV light from the backside of PV cell(s) 126, which is typically mounted on the transparent glass substrate 104. This method may help to ensure that UV light passes primarily through the defects, as they may be the only clear paths allowing light penetration. The negative photoresist may cure inside these defects where the UV light exposure occurs, forming a robust protective layer precisely within the holes or gaps. This selective curing may, for example, reinforce the structural integrity of PV cell(s) 126, particularly at vulnerable points, effectively preventing degradation during the electrolysis of water.

FIG. 4 depicts an assembled hydrogen module 400 in accordance with one or more embodiments. Multiple PV submodules (e.g., Hydrogen submodules) 100 (e.g., submodules 100a-100g) assembled on a single substrate to form a PV module 200 (e.g., a Hydrogen module 400). Within this module, hydrogen and oxygen evolution may occur in repetitive linear patterns. In some embodiments, a suitable reactor design may facilitate the separation of gases (e.g., hydrogen and oxygen), ensuring that each type is collected independently and efficiently. PV submodules and PV modules may not have catalyst coatings. Modules with catalyst coatings may be referred to as Hydrogen submodules and Hydrogen modules.

In some embodiments, a PV module includes a plurality of PV submodules connected in parallel and coated with oxygen evolution catalyst (OEC) 402 and hydrogen evolution catalyst (HEC) 404, forming Hydrogen modules 400. Such OEC 402 or HEC 404 may, for example, be coupled to the metal conductor, using conductive pastes, adhesives, tapes, soldering, welding or the like. Hydrogen modules 400 and submodules 100 may be integrated with specialized electrocatalysts on the anode to facilitate a variety of oxidation reactions, in addition to oxygen evolution. Such electrocatalysts may be designed to target specific reactions that can purify water by breaking down organic contaminants through oxidation processes, or by generating industrially valuable chemicals. For instance, in the presence of chloride ions commonly found in seawater or certain wastewater streams, the employed electrocatalysts may facilitate the production of chlorine or hypochlorite. Similarly, when bromide ions are present, the system may produce bromine. Additionally, in some embodiments, these electrocatalysts are optimized to generate other chemicals, such as hydrogen peroxide (H₂O₂) and ozone (O₃), which may be potent oxidizing agents used for water disinfection and pollution control. The flexibility in catalyst formulation may, for example, provide for the treatment of a wide range of organic compounds and the production of various chemicals, which may, for example, make the system a versatile tool for environmental remediation and chemical synthesis.

FIGS. 5A and 5B illustrate example manufacturing processes for Hydrogen modules in accordance with one or more embodiments. For example, FIG. 5A illustrates an example manufacturing process 500 for Hydrogen modules 400 (e.g., PV modules 100) showing a zoomed-in cross-sectional view of two CdTe layers connected in series. Such a process may include, for example, the following: (1) forming/providing a glass substrate (e.g., glass substrate 104); (2) depositing a TCO layer (e.g., TCO layer 106) on the glass substrate; (3) scribing to divide TCO layers for isolation (e.g., represented by P1); (4) depositing a semiconductor absorber as a PV layer (e.g., CdTe layer 108); (5) scribing to disconnect PV layers to form a number of unit PV layers (e.g., represented by P2); (6) depositing of a metal back contact layer (e.g., back contact layer 110); (7) scribing to electrically disconnect the metal contacts and to isolate two PV layers forming one PV module (e.g., represented by P3); (8) applying insulating and protecting material (e.g., epoxy forming insulator/protector, a tape or film applied via a pressure-sensitive or a heat-sensitive adhesive, a photoresist, or a material resistant to acidic or alkaline electrolytes 502); (9) scribing to expose a portion of anode and cathode surfaces (e.g., represented by P4); (10) depositing a metal conductor on the exposed cathode and anode surface that serve as current collectors (e.g., titanium forming metal conductor 504); (11) depositing a coating of HER and/or OER catalysts on the metal conductor (e.g., on respective ones of cathode 506 and anode 508); and (12) sealing the edges of the catalyst layers with insulting and protecting material (e.g., material 509).

FIG. 5B illustrates a second example of manufacturing process 550 for Hydrogen modules showing a zoomed-in cross-sectional view of two CdTe layers connected in series. Such a process may include, for example, the following: (1) providing a glass substrate (e.g., glass substrate 104); (2) depositing a TCO layer (e.g., TCO layer 106), or “coating,” on the glass substrate; (3) depositing a semiconductor absorber as a PV layer (e.g., CdTe layer 108); (4) scribing to divide the TCO and absorber layers for isolation (e.g., represented by P1); (5) depositing an insulator inside the scribed patterns (e.g., photoresist forming insulator 552); (6) scribing to disconnect PV layers to form a number of unit PV layers (e.g., represented by P2); (7) deposition of metal back contact layer (e.g., back contact layer 110); (8) scribing to electrically disconnect the metal contacts and to isolate two PV layers forming one PV module (e.g., represented by P3); (9) applying insulating and protecting material (e.g., epoxy or photoresist forming insulator/protector 554); (10) scribing to expose a portion of anode and cathode surfaces (e.g., represented by P4); (11) depositing a metal conductor on the exposed cathode and anode surface (e.g., titanium forming metal conductor 556); (12) depositing a coating of HER and OER catalysts on the metal conductor (e.g., cathode 558 and anode 560); (13) sealing the edges of the catalyst layers with insulting and protecting material (e.g., material 561); and (14) integrating membrane separators (e.g., separator 562).

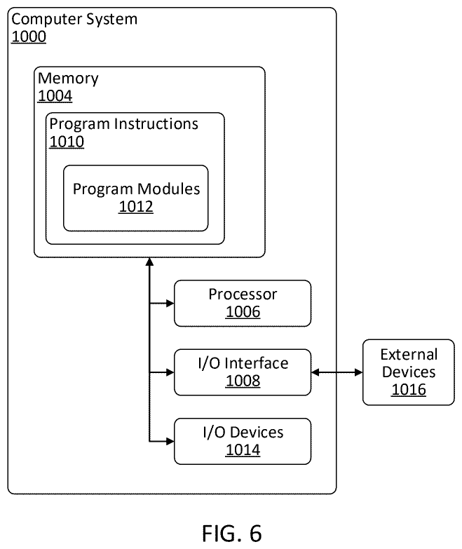

In some embodiments, the method operations described here may be performed by a system or other operator, such as person. In the case of a system, the system may include a computer controller, or similar control device, that is operable to cause the method operations described. Such a computer may include memory having program instructions stored thereon that are executable by a processor of the computer to perform the operations described. Such a computer may include a computer system that is the same or similar to computer system 1000 described with regard to FIG. 6.

FIG. 6 is a diagram that illustrates an example computer system (or “system”) 1000 in accordance with one or more embodiments. System 1000 may include a memory 1004, a processor 1006 and an input/output (I/O) interface 1008. Memory 1004 may include non-volatile memory (e.g., flash memory, read-only memory (ROM), programmable read-only memory (PROM), erasable programmable read-only memory (EPROM), electrically erasable programmable read-only memory (EEPROM)), volatile memory (e.g., random access memory (RAM), static random access memory (SRAM), synchronous dynamic RAM (SDRAM)), or bulk storage memory (e.g., CD-ROM or DVD-ROM, hard drives). Memory 1004 may include a non-transitory computer-readable storage medium having program instructions 1010 stored on the medium. Program instructions 1010 may include, for example, program modules 1012 that are executable by a computer processor (e.g., processor 1006) to cause the functional operations described, such as those described with regard to processes 500 and 500.

Processor 1006 may be any suitable processor capable of executing program instructions. Processor 1006 may include one or more processors that carry out program instructions (e.g., the program instructions of program modules 1012) to perform the arithmetical, logical, or input/output operations described. Processor 1006 may include multiple processors that can be grouped into one or more processing cores that each include a group of one or more processors that are used for executing the processing described here. I/O interface 1008 may provide an interface for communication with one or more I/O devices 1014, such as a joystick, a computer mouse, a keyboard, or a display screen (e.g., an electronic display for displaying a graphical user interface (GUI)). I/O devices 1014 may include one or more of the user input devices. I/O devices 1014 may be connected to I/O interface 1008 by way of a wired connection (e.g., an Industrial Ethernet connection) or a wireless connection (e.g., a Wi-Fi connection). I/O interface 1008 may provide an interface for communication with one or more external devices 1016, computer systems, servers or electronic communication networks. In some embodiments, I/O interface 1008 includes an antenna or a transceiver.

The described embodiments may be better understood in view of the following example enumerated embodiments:
1. A method for water electrolysis, comprising:
   connecting photovoltaic (PV) cells;
   deposition and scribing of one or more layers to provide delineation or electrical linkage of semiconductor layers associated with the PV cells; and
   deposition and coating of protective layers and catalysts on the PV cells.
2. A system for water electrolysis, comprising:
   connected photovoltaic (PV) cells;
   one or more layers deposited and scribed to provide delineation or electrical linkage of semiconductor layers associated with the PV cells; and
   one or more protective layers and catalysts deposited on the PV cells.
3. A method for generating enhanced photovoltage optimized for water electrolysis, involving:
   the serial connection of multiple photovoltaic (PV) cells within a submodule to produce a cumulative photovoltage exceeding 1.6 volts;
   the use of scribing techniques for the delineation and electrical linkage of individual semiconductor layers; and
   the application of a diversified set of deposition techniques for the construction of PV cells, involving layer formation of transparent conductive oxides, various semiconductors, and metals.
4. The method of embodiment 3, wherein the semiconductors utilized in the PV cells include, but are not limited to, cadmium telluride (CdTe), cadmium selenide (CdSe), silicon (Si), gallium arsenide (GaAs), copper indium gallium selenide (CIGS), and perovskite, and a combination of thereof.
5. The method of embodiment 3, further characterized by the incorporation of laser scribing, or chemical etching for enhanced precision in the formation of PV cells and the assembly of modules, facilitating accurate separation and connection of semiconductor layers.
6. The method of embodiment 3, wherein the deposition processes comprise a range of techniques including electron-beam evaporation, sputtering, thermal evaporation, electroplating, spray coating, and close space sublimation, each selected based on material compatibility and desired layer properties.
7. A method for applying a protective layer on photovoltaic (PV) cells, comprising:
   spin, blade, brush coating of anti-corrosion polymer onto the surface of the PV cells;
   spin-coating a photoresist onto the surface of the PV cells;
   illuminating the coated surface with ultraviolet (UV) light for curing the photoresist, wherein the method includes two distinct approaches based on the type of photoresist used:
   a. for positive photoresists, directing UV light onto the top surface of the PV cell, such that areas with defects receive less light, thereby allowing the uncured photoresist in these areas to remain post-development and provide a protective barrier;
   b. for negative photoresists, directing UV light from the backside of the PV cell, which is mounted on a transparent substrate, ensuring that UV light passes predominantly through defects, curing the photoresist specifically within these defects to form a durable protective layer.
8. The method of embodiment 7,
   wherein the anti-corrosion polymers utilized may include, but not limited to, polyurethane, acrylic, and epoxy; and
   wherein the protective layer selectively covers the external areas of the cathodes and anodes to prevent corrosion within the scribed patterns of the PV cells.
9. The method of embodiment 7, wherein the protective layer formed using negative photoresist selectively reinforces the structural integrity by filling the defective pores of the PV cells at points of vulnerability, thereby enhancing the cells'resistance to environmental stressors encountered during water electrolysis processes.
10. The method of embodiment 7, wherein the protective layer formed using positive photoresist acts to safeguard the electrical properties by filling the defective pores of the PV cells by preventing corrosive degradation during electrolysis, ensuring prolonged operational efficiency.
11. A method for water splitting, comprising:
   conducting water splitting using a hydrogen module comprising:
   PV cells linked to form one or more submodules, each configured to generate photovoltage configured to drive electrolysis of water;
   hydrogen evolution reaction (HER) catalysts deposited on one or more designated cathode regions; and
   oxygen evolution reaction (OER) catalysts deposited on one or more designated anode regions.
12. A system for water splitting, comprising:
   a hydrogen module comprising:
   PV cells linked to form one or more submodules, each configured to generate photovoltage configured to drive electrolysis of water;
   hydrogen evolution reaction (HER) catalysts deposited on one or more designated cathode regions; and
   oxygen evolution reaction (OER) catalysts deposited on one or more designated anode regions.
13. A hydrogen module for water splitting, featuring:
   a substrate with a series of PV cells linked in series to form one or several submodules, each designed to generate photovoltage capable of driving electrolysis of water;
   hydrogen evolution reaction (HER) catalysts deposited on designated cathode regions; and
   oxygen evolution reaction (OER) catalysts deposited on designated anode regions.
14. The hydrogen module of embodiment 13, wherein the catalysts are deposited using techniques including electroplating, e-beam evaporation, sputtering, spray coating, blade coating, brush coating, thermal oxidation and a combination of thereof.
15. The hydrogen module of embodiment 13, wherein the substrate is fabricated from materials such as glass, flexible polymers, or ceramics, tailored to enhance the durability and performance of the PV cells.
16. A hydrogen module of embodiment 13, configured for:
   a. the oxidation of organic contaminants to purify water sources;
   b. the production of industrially valuable chemicals such as chlorine from chloride ions and bromine from bromide ions;
   c. the generation of hydrogen peroxide (H₂O₂) and ozone (O₃) for use in water disinfection and pollution control.
17. The hydrogen module of embodiment 13, wherein the electrocatalysts are specifically formulated to target and break down various organic compounds through oxidation, enhancing the purification process of contaminated water sources.
18. The hydrogen module or submodule of embodiment 13, wherein the electrocatalysts are capable of reacting with specific ions present in the water to produce desired chemicals, thereby providing a dual function of water treatment and chemical synthesis.
19. The hydrogen module or submodule of embodiment 13, further comprising a system for regulating the exposure of water to the electrocatalysts, thereby optimizing the efficiency of the oxidation reactions and the yield of produced chemicals.
20. A system for water electrolysis, comprising:
   a glass substrate layer;
   a transparent conductive oxide (TCO) layer adjacent the glass substrate layer and comprising one or more TCO electrical disconnects formed in the TCO to define discrete TCO regions;
   a photovoltaic (PV) layer adjacent the transparent conductive oxide layer and comprising a window layer and a graded absorber layer, the PV layer having one or more PV electrical disconnects formed in the PV layer to define discrete PV regions, one or more portions of the PV layer extending into the one or more TCO electrical disconnects and being adjacent the glass substrate layer;
   a metal back contact (MBC) layer adjacent the PV layer and comprising one or more MBC electrical disconnects formed in the MBC layer to define discrete MBC regions, one or more portions of the MBC layer extending into the one or more PV electrical disconnects and being adjacent the TCO layer;
   an insulating layer adjacent the MBC layer and comprising one or more insulating voids formed in the insulating layer to expose anode and cathode portions of the MBC layer, one or more portions of the insulating layer extending into the one or more MBC electrical disconnects and being adjacent the TCO layer;
   a metal conductor layer adjacent the insulating layer and comprising a metal conductor extending into insulating voids to form metal conductors electrically coupled to the exposed anode and cathode portions of the MBC layer;
   an oxygen evolution catalyst coating on the metal conductors electrically coupled to the exposed anode portions of the MBC layer; and
   a hydrogen evolution catalyst coating on the metal conductors electrically coupled to the exposed cathode portions of the MBC layer.
21. The system of embodiment 20, wherein the PV layer comprises a semiconductor material.
22. The system of embodiment 20 or 21, wherein the PV layer comprises or more of: cadmium telluride (CdTe), cadmium selenide (CdSe), silicon (Si), gallium arsenide (GaAs), copper indium gallium selenide (CIGS), or perovskite.
23. The system of any one of embodiments 20-22, wherein the window layer, graded absorber layer and PV layer comprise CdS, CdSeTe, and cadmium telluride (CdTe).
24. The system of any one of embodiments 20-23, wherein:
   the one or more TCO electrical disconnects are scribed in the TCO layer, the the one or more PV electrical disconnects are scribed into the PV layer,
   the one or more MBC electrical disconnects are scribed into the MBC layer, and
   the one or more insulating voids are scribed into the insulating layer.
25. The system of any one of embodiments 20-24, wherein a pair of discrete PV regions are coupled in series to form a PV submodule.
26. The system of any one of embodiments 20-25, wherein multiple pairs of discrete PV regions are coupled in series to form PV submodules defining a PV module.
27. A method for producing a system for water electrolysis, comprising:
   providing a glass substrate layer;
   forming a transparent conductive oxide (TCO) layer adjacent the glass substrate layer and comprising one or more TCO electrical disconnects formed in the TCO to define discrete TCO regions;
   forming a photovoltaic (PV) layer adjacent the transparent conductive oxide layer and comprising a window layer and a graded absorber layer, with one or more PV electrical disconnects formed in the PV layer to define discrete PV regions, one or more portions of the PV layer extending into the one or more TCO electrical disconnects and being adjacent the glass substrate layer;
   forming a metal back contact (MBC) layer adjacent the PV layer and comprising one or more MBC electrical disconnects formed in the MBC layer to define discrete MBC regions, one or more portions of the MBC layer extending into the one or more PV electrical disconnects and being adjacent the TCO layer;
   forming an insulating layer adjacent the MBC layer and comprising one or more insulating voids formed in the insulating layer to expose anode and cathode portions of the MBC layer, one or more portions of the insulating layer extending into the one or more MBC electrical disconnects and being adjacent the TCO layer;
   forming a metal conductor layer adjacent the insulating layer and comprising a metal conductor extending into insulating voids to form metal conductors electrically coupled to the exposed anode and cathode portions of the MBC layer;
   forming an oxygen evolution catalyst coating on the metal conductors electrically coupled to the exposed anode portions of the MBC layer; and
   forming a hydrogen evolution catalyst coating on the metal conductors electrically coupled to the exposed cathode portions of the MBC layer.
28. The method of embodiment 27, wherein the PV layer comprises a semiconductor material.
29. The method of embodiment 27 or 28, wherein the PV layer comprises or more of: cadmium telluride (CdTe), cadmium selenide (CdSe), silicon (Si), gallium arsenide (GaAs), copper indium gallium selenide (CIGS), or perovskite.
30. The method of any one of embodiments 27-29, wherein the PV layer comprises cadmium telluride (CdTe).
31. The method of any one of embodiments 27-30, further comprising:
   scribing the one or more TCO electrical disconnects in the TCO layer,
   scribing the one or more PV electrical disconnects into the PV layer,
   scribing the one or more MBC electrical disconnects into the MBC layer, and
   scribing the one or more the one or more insulating voids into the insulating layer.
32. The method of any one of embodiments 27-31, further comprising coupling a pair of discrete PV regions in series to form a PV submodule.
33. The method of any one of embodiments 27-32, further comprising coupling multiple pairs of discrete PV regions in series to form PV submodules defining a PV module.
34. Non-transitory computer-readable storage medium comprising program instructions stored thereon that are executable by a processor to cause the operations of any one of embodiments 27-33.

What is claimed is:

1. A system for water electrolysis, comprising:
a glass substrate layer;
a transparent conductive oxide (TCO) layer adjacent the glass substrate layer and comprising one or more TCO electrical disconnects formed in the TCO to define discrete TCO regions;
a photovoltaic (PV) layer adjacent the transparent conductive oxide layer and comprising one or more PV electrical disconnects formed in the PV layer to define discrete PV regions, one or more portions of the PV layer extending into the one or more TCO electrical disconnects and being adjacent the glass substrate layer;
a metal back contact (MBC) layer adjacent the PV layer and comprising one or more MBC electrical disconnects formed in the MBC layer to define discrete MBC regions, one or more portions of the MBC layer extending into the one or more PV electrical disconnects and being adjacent the TCO layer;
an insulating layer adjacent the MBC layer and comprising one or more insulating voids formed in the insulating layer to expose anode and cathode portions of the MBC layer, one or more portions of the insulating layer extending into the one or more MBC electrical disconnects and being adjacent the TCO layer;
a metal conductor layer adjacent the insulating layer and comprising a metal conductor extending into insulating voids to form metal conductors electrically coupled to the exposed anode and cathode portions of the MBC layer;
an oxygen evolution catalyst coating on the metal conductors electrically coupled to the exposed anode portions of the MBC layer; and
a hydrogen evolution catalyst coating on the metal conductors electrically coupled to the exposed cathode portions of the MBC layer.

2. The system of claim 1, wherein the PV layer comprises a semiconductor material, and comprises a window layer and a graded absorber layer.

3. The system of claim 1, wherein the PV layer comprises one or more of: cadmium telluride (CdTe), cadmium selenide (CdSe), silicon (Si), gallium arsenide (GaAs), copper indium gallium selenide (CIGS), or perovskite.

4. The system of claim 1, wherein the PV layer comprises cadmium telluride (CdTe).

5. The system of claim 1, wherein:
the one or more TCO electrical disconnects are scribed in the TCO layer,
the one more PV electrical disconnects are scribed into the PV layer,
the one or more MBC electrical disconnects are scribed into the MBC layer, and
the one or more insulating voids are scribed into the insulating layer.

6. The system of claim 1, wherein a pair of discrete PV regions are coupled in series to form a PV submodule.

7. The system of claim 1, wherein multiple pairs of discrete PV regions are coupled in series to form PV submodules defining a PV module.

8. A method for producing a system for water electrolysis, comprising:
providing a glass substrate layer;
forming a transparent conductive oxide (TCO) layer adjacent the glass substrate layer and comprising one or more TCO electrical disconnects formed in the TCO to define discrete TCO regions;
forming a photovoltaic (PV) layer adjacent the transparent conductive oxide layer and comprising one or more PV electrical disconnects formed in the PV layer to define discrete PV regions, one or more portions of the PV layer extending into the one or more TCO electrical disconnects and being adjacent the glass substrate layer;
forming a metal back contact (MBC) layer adjacent the PV layer and comprising one or more MBC electrical disconnects formed in the MBC layer to define discrete MBC regions, one or more portions of the MBC layer extending into the one or more PV electrical disconnects and being adjacent the TCO layer;
forming an insulating layer adjacent the MBC layer and comprising one or more insulating voids formed in the insulating layer to expose anode and cathode portions of the MBC layer, one or more portions of the insulating layer extending into the one or more MBC electrical disconnects and being adjacent the TCO layer;
forming a metal conductor layer adjacent the insulating layer and comprising a metal conductor extending into insulating voids to form metal conductors electrically coupled to the exposed anode and cathode portions of the MBC layer;
forming an oxygen evolution catalyst coating on the metal conductors electrically coupled to the exposed anode portions of the MBC layer; and
forming a hydrogen evolution catalyst coating on the metal conductors electrically coupled to the exposed cathode portions of the MBC layer.

9. The method of claim 8, wherein the PV layer comprises a semiconductor material, and comprises a window layer and a graded absorber layer.

10. The method of claim 8, wherein the PV layer comprises one or more of: cadmium telluride (CdTe), cadmium selenide (CdSe), silicon (Si), gallium arsenide (GaAs), copper indium gallium selenide (CIGS), or perovskite.

11. The method of claim 8, wherein the PV layer comprises cadmium telluride (CdTe).

12. The method of claim 8, further comprising:
scribing the one or more TCO electrical disconnects in the TCO layer,
scribing the one or more PV electrical disconnects into the PV layer,
scribing the one or more MBC electrical disconnects into the MBC layer, and
scribing the one or more the one or more insulating voids into the insulating layer.

13. The method of claim 8, coupling a pair of discrete PV regions in series to form a PV submodule.

14. The method of claim 8, coupling multiple pairs of discrete PV regions in series to form PV submodules defining a PV module.

15. Non-transitory computer-readable storage medium comprising program instructions stored thereon that are executable by a processor to cause the following operations for producing a system for water electrolysis, comprising:
forming a transparent conductive oxide (TCO) layer adjacent a glass substrate layer and comprising one or more TCO electrical disconnects formed in the TCO to define discrete TCO regions;
forming a photovoltaic (PV) layer adjacent the transparent conductive oxide layer and comprising one or more PV electrical disconnects formed in the PV layer to define discrete PV regions, one or more portions of the PV layer extending into the one or more TCO electrical disconnects and being adjacent the glass substrate layer;
forming a metal back contact (MBC) layer adjacent the PV layer and comprising one or more MBC electrical disconnects formed in the MBC layer to define discrete MBC regions, one or more portions of the MBC layer extending into the one or more PV electrical disconnects and being adjacent the TCO layer;
forming an insulating layer adjacent the MBC layer and comprising one or more insulating voids formed in the insulating layer to expose anode and cathode portions of the MBC layer, one or more portions of the insulating layer extending into the one or more MBC electrical disconnects and being adjacent the TCO layer;
forming a metal conductor layer adjacent the insulating layer and comprising a metal conductor extending into insulating voids to form metal conductors electrically coupled to the exposed anode and cathode portions of the MBC layer;
forming an oxygen evolution catalyst coating on the metal conductors electrically coupled to the exposed anode portions of the MBC layer; and
forming a hydrogen evolution catalyst coating on the metal conductors electrically coupled to the exposed cathode portions of the MBC layer.

16. The medium of claim 15, wherein the PV layer comprises a semiconductor material, and comprises a window layer and a graded absorber layer.

17. The medium of claim 15, wherein the PV layer comprises or more of: cadmium telluride (CdTe), cadmium selenide (CdSe), silicon (Si), gallium arsenide (GaAs), copper indium gallium selenide (CIGS), or perovskite.

18. The medium of claim 15, wherein the PV layer comprises cadmium telluride (CdTe).

19. The medium of claim 15, the operations further comprising:
scribing the one or more TCO electrical disconnects in the TCO layer,
scribing the one or more PV electrical disconnects into the PV layer,
scribing the one or more MBC electrical disconnects into the MBC layer, and
scribing the one or more the one or more insulating voids into the insulating layer.

20. The medium of claim 15, the operations further comprising coupling a pair of discrete PV regions in series to form a PV submodule.

21. The medium of claim 15, the operations further comprising coupling multiple pairs of discrete PV regions in series to form PV submodules defining a PV module.
